(19) United States
(12) Patent Application Publication
(10) Pub. No.: US 2025/0279327 A1
(43) Pub. Date: Sep. 4, 2025

(54) SEMICONDUCTOR DEVICE

(71) Applicant: FUJI ELECTRIC CO., LTD., Kanagawa (JP)

(72) Inventor: Yasufumi HARA, Matsumoto-city (JP)

(21) Appl. No.: 19/037,267

(22) Filed: Jan. 26, 2025

(30) Foreign Application Priority Data
Feb. 29, 2024 (JP) 2024-030805

(51) Int. Cl. H01L 23/34; H10D 12/00; H10D 64/00

(52) U.S. Cl. CPC H01L 23/34; H10D 12/481; H10D 64/117

(57) ABSTRACT

Provided is a semiconductor device including a semiconductor substrate, where the semiconductor substrate has: a temperature sensing diode provided above an upper surface of the semiconductor substrate; a diode wiring provided above the upper surface of the semiconductor substrate and connected to the temperature sensing diode; a metal layer provided in at least part of a region between the diode wiring and the upper surface of the semiconductor substrate; a first interlayer dielectric film provided between the metal layer and the upper surface of the semiconductor substrate; and a second interlayer dielectric film provided between the diode wiring and the metal layer.

### The contents of the following patent application(s) are incorporated herein by reference: NO. 2024-030805 filed in JP on Feb. 29, 2024.

### BACKGROUND

### 1. Technical Field

The present invention relates to a semiconductor device.

### 2. Related Art

In the related art, a semiconductor device has been known in which a thermosensitive element can be disposed in a state where the element is electrically separated from a semiconductor substrate without being limited by the diffusing structure of a semiconductor layer underlying the thermosensitive element (see Patent Document 1, for example). In addition, a semiconductor device has been known which comprises a temperature sense part having a stable temperature detection accuracy while suppressing increase in chip area (See Patent Document 2, for example).

### Prior Art Documents

### Patent Documents

Patent Document 1: Japanese Patent Application Publication No. 2005-26279
Patent Document 2: Japanese Patent No. 6872933

### BRIEF DESCRIPTION OF THE DRAWINGS

FIG. 1A illustrates a top view of one example of a semiconductor device 100 according to one embodiment of the present invention.

FIG. 1B illustrates arrangement of a temperature sensing diode 66, a diode wiring 60, and a metal layer 80 in a top view.

FIG. 2 illustrates one example of the semiconductor device 100 in a cross section A-A′ shown in FIG. 1B.

FIG. 3 illustrates a cross section A-A′ of a semiconductor device 200 according to a comparative example.

FIG. 4 illustrates one example of the semiconductor device 100 in a cross section B-B′ shown in FIG. 1B.

FIG. 5 illustrates one example of the semiconductor device 100 in a cross section C-C′ shown in FIG. 1B.

FIG. 6 illustrates one example of a top view of the semiconductor device 100.

FIG. 7 illustrates one example of the semiconductor device 100 in a cross section D-D′ shown in FIG. 6.

FIG. 8 illustrates a top view of one example of a semiconductor device 300 according to another embodiment of the present invention.

FIG. 9 illustrates one example of the semiconductor device 300 in a cross section D-D′ shown in FIG. 8.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to a solution of the invention. It should be noted that, for elements having substantially a same function and configuration in the present specification and drawings, a same reference numeral will be given to the elements to avoid redundant description thereof, and elements which are not directly related to the present invention will not be shown. In addition, for elements having substantially a same function and configuration in one drawing, a reference numeral may be given to an element as a representative, and for the rest of the elements, the reference numeral may not be given.

In the present specification, one side in a direction parallel to a depth direction of a semiconductor substrate is referred to as “upper” and another side is referred to as “lower”. One surface of two principal surfaces of a substrate, a layer, or another member is referred to as an upper surface, and another surface is referred to as a lower surface. “Upper” and “lower” directions are not limited to a direction of gravity, or a direction in which a semiconductor module is mounted.

In the present specification, technical matters may be described using orthogonal coordinate axes of an X axis, a Y axis, and a Z axis. The orthogonal coordinate axes merely specify relative positions of components, and do not limit a specific direction. For example, a Z axis is not limited to indicate the height direction with respect to the ground. It should be noted that a +Z axis direction and a −Z axis direction are directions opposite to each other. If a Z axis direction is described without describing the signs, it means that the direction is parallel to a +Z axis and a −Z axis. In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A case where a term such as “same” or “equal” is used in the present specification may include a case where an error due to a variation in manufacturing or the like is included. The error is, for example, within 10%.

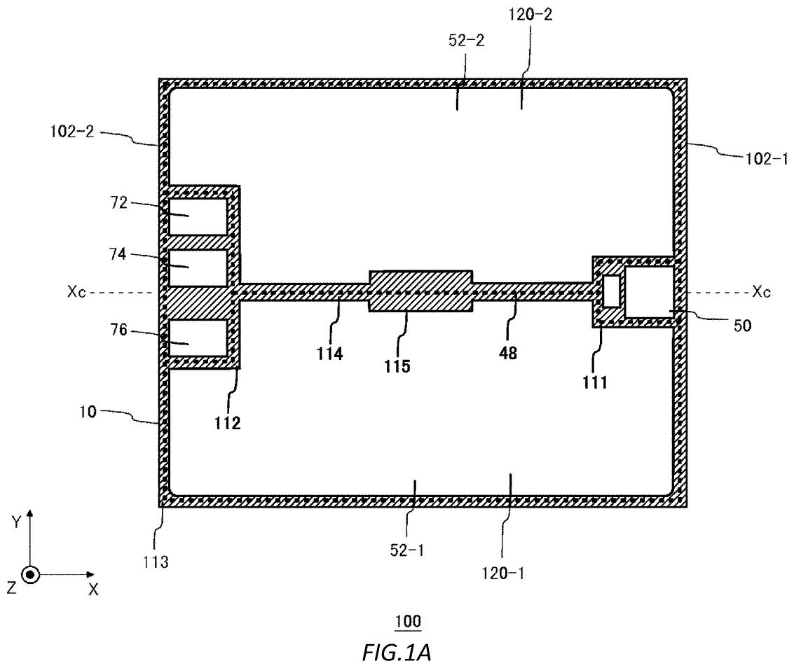

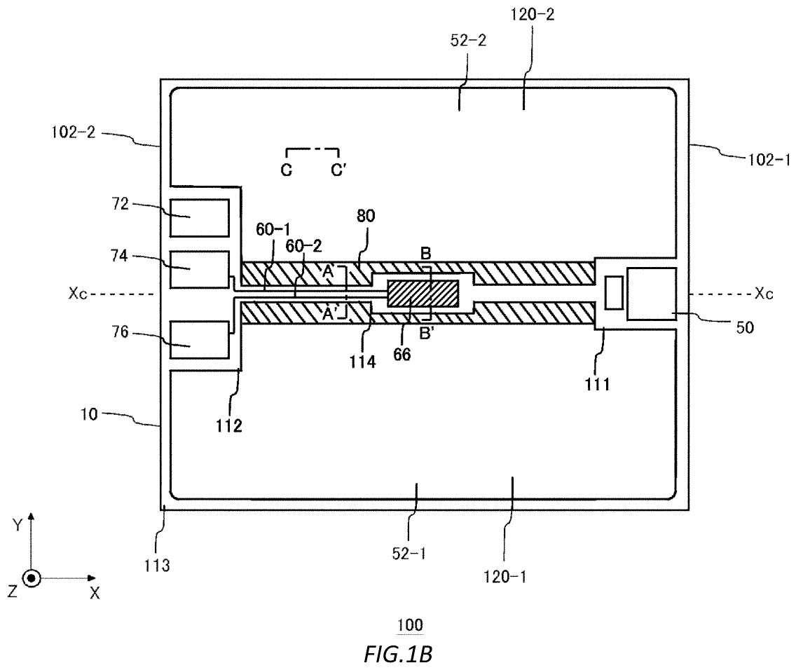

FIG. 1A illustrates a top view of one example of a semiconductor device 100 according to one embodiment of the present invention. FIG. 1A shows a position obtained by projecting a position of each member onto an upper surface of a semiconductor substrate 10. FIG. 1A shows only some members of the semiconductor device 100, and does not show some members.

The semiconductor device 100 includes the semiconductor substrate 10. The semiconductor substrate 10 is a substrate made of a compound semiconductor such as silicon or SiC. The semiconductor substrate 10 includes an end side 102 in a top view. The semiconductor substrate 10 in the present example includes two sets of end sides 102 opposite each other in a top view. FIG. 1A shows one set of end sides 102-1 and 102-2 opposite each other. In FIG. 1A, a direction parallel to the end side 102-1 and the end side 102-2 is referred to as a Y axis direction, and a direction perpendicular to the end side 102-1 and the end side 102-2 is referred to as an X axis direction.

The semiconductor substrate 10 is provided with an active portion 120. The semiconductor substrate 10 in the present example is provided with an active portion 120-1 and an active portion 120-2. The active portion 120 is a region through which a main current flows in a depth direction between the upper surface and a lower surface of the semiconductor substrate 10 if the semiconductor device 100 is controlled to be in an on-state.

The active portion 120 is provided with a semiconductor element. The semiconductor element may be a transistor element such as an IGBT, may be a diode element such as an FWD, or may be both of them.

The semiconductor device 100 includes an upper surface electrode 52 provided above the upper surface of the semiconductor substrate 10. The upper surface electrode 52 is provided above the active portion 120. The upper surface electrode 52 may be provided above each active portion 120. The semiconductor device 100 in the present example includes an upper surface electrode 52-1 and an upper surface electrode 52-2. The upper surface electrode 52-1 is provided above the active portion 120-1, and the upper surface electrode 52-2 is provided above the active portion 120-2. In the present specification, the upper surface electrode 52-1 and the upper surface electrode 52-2 may respectively be referred to as a first portion and a second portion. The upper surface electrode 52 is, for example, an Al-Si alloy.

The upper surface electrode 52-1 and the upper surface electrode 52-2 may be electrically connected to each other via at least one of a metal layer, solder, or a lead frame described later. The upper surface electrode 52 may be an electrode having largest area in a top view among electrodes provided above the upper surface of the semiconductor substrate 10. The upper surface electrode 52 may be electrically connected to an emitter region or a source region of a transistor portion, or may be electrically connected to an anode region of a diode portion. The active portion 120 may be a region overlapping with the upper surface electrode 52 in a top view.

The semiconductor substrate 10 is provided with a well region of a P type. The well region is a P type region having a higher concentration than a base region of the transistor portion or the anode region of the diode portion. The base region is a P type region: provided facing a conductive portion of a gate electrode; and having a channel formed in a portion facing the conductive portion if a predetermined gate voltage is applied to the conductive portion. The semiconductor substrate 10 includes a first well region 111 and a second well region 112. The first well region 111 and the second well region 112 are provided sandwiching the active portion 120 in a top view. The first well region 111 and the second well region 112 are provided sandwiching the active portion 120 in a predetermined direction (the X axis direction in FIG. 1A). The two well regions sandwiching the active portion 120 means that any straight line connecting the two well regions in a top view passes through the active portion 120. The first well region 111 and the second well region 112 in the present example are both rectangular shaped. In FIG. 1A, the first well region 111 and the second well region 112 are hatched.

The first well region 111 may be provided near the end side 102-1. That is, a distance between the first well region 111 and the end side 102-1 is smaller than a distance between the first well region 111 and the end side 102-2. The second well region 112 may be provided near the end side 102-2. That is, a distance between the second well region 112 and the end side 102-2 is smaller than a distance between the second well region 112 and the end side 102-1.

The first well region 111 in the present example is provided between the active portion 120 and the end side 102-1 in the X axis direction. The active portion 120 is not provided between the first well region 111 and the end side 102-1. That is, the first well region 111 is provided between an end portion of the active portion 120 in the X axis direction and the end side 102-1.

The second well region 112 in the present example is provided between the active portion 120 and the end side 102-2 in the X axis direction. The active portion 120 is not provided between the second well region 112 and the end side 102-2. That is, the second well region 112 is provided between an end portion of the active portion 120 in the X axis direction and the end side 102-2.

The first well region 111 and the second well region 112 may be provided in a range including a central position Xc of the end side 102-1 and the end side 102-2 in the Y axis direction. The first well region 111 may be sandwiched between active portions 120 in the Y axis direction. The second well region 112 may be sandwiched between the active portions 120 in the Y axis direction. The second well region 112 may be provided in a range which is wider than the first well region 111 in the Y axis direction.

The semiconductor substrate 10 may include a peripheral well region 113 provided enclosing the active portion 120 in a top view. The peripheral well region 113 may be provided parallel to each end side of the semiconductor substrate 10. The peripheral well region 113 is in contact with each end side of the semiconductor substrate 10 in FIG. 1A, but the peripheral well region 113 may be away from each end side. The peripheral well region 113 in the present example is an annular region enclosing the active portion 120 in a top view. The peripheral well region 113 may have a constant width in a direction perpendicular to each end side. In FIG. 1A, the peripheral well region 113 is also hatched. It is to be noted that portions, which overlap with a gate pad 50, a current detection pad 72, an anode pad 74, and a cathode pad 76, of respective well regions are not hatched.

The first well region 111 and the second well region 112 in the present example protrude farther toward a center of the active portion 120 than the peripheral well region 113. In another example, at least one of the first well region 111 or the second well region 112 may be provided between the peripheral well region 113 and the end side 102 of the semiconductor substrate 10. In this case, the first well region 111 and the second well region 112 protrude from the peripheral well region 113 toward the end side 102.

The semiconductor substrate 10 may include a dividing well region 114 which divides the active portion 120 in a top view. The active portion 120 may be divided into the active portion 120-1 and the active portion 120-2 by a well region including the dividing well region 114. The dividing well region 114 is sandwiched between the active portions 120 in a top view. The dividing well region 114 has a longitudinal part in a predetermined well longitudinal direction. The dividing well region 114 extends in the well longitudinal direction to cross the active portion 120. The well longitudinal direction of the dividing well region 114 is the X axis direction. In FIG. 1A, the dividing well region 114 is also hatched.

The dividing well region 114 may be provided between the first well region 111 and the second well region 112. One end and another end, in a longitudinal direction, of the dividing well region 114 may respectively be connected to the first well region 111 and the second well region 112. The dividing well region 114 may be provided in a region overlapping with the center of the active portion 120.

The dividing well region 114 may include a wide portion 115 having a width larger than that of another portion in a direction perpendicular to the well longitudinal direction in a top view (the Y axis direction in the present example). The wide portion 115 is also provided between the first well region 111 and the second well region 112. The wide portion 115 may be provided in a region overlapping with the center of the active portion 120. The wide portion 115 may be provided in a region including a center of the dividing well region 114 in the well longitudinal direction.

The semiconductor substrate 10 in the present example includes control electrodes such as the gate pad 50, the current detection pad 72, the anode pad 74, and the cathode pad 76. The gate pad 50 is provided above the first well region 111. The current detection pad 72, the anode pad 74, and the cathode pad 76 are provided above the second well region 112.

A predetermined gate voltage is applied to the gate pad 50. The gate voltage applied to the gate pad 50 is supplied to a transistor portion of the active portion 120 by a gate runner 48 described later or the like.

The semiconductor substrate 10 includes the gate runner 48 provided above the upper surface of the semiconductor substrate 10. In FIG. 1A, the gate runner 48 is indicated by a dashed line. In the present example, the gate runner 48 is a wiring made of polysilicon to which an impurity is added. The gate runner 48 may be made of a conductive material such as a metal. The gate runner 48 supplies the gate voltage applied to the gate pad 50 to the transistor portion provided in the active portion 120.

The gate runner 48 may be provided above each well region. Part of the gate runner 48 may be provided along the peripheral well region 113 so as to enclose the active portion 120. In addition, another gate runner 48 may also be provided between each control electrode and the active portion 120 along the first well region 111 and the second well region 112. Another gate runner 48 may be provided above the dividing well region 114, and may overlap with a temperature sensing diode 66 and a diode wiring 60 described later. That is, the gate runner 48 in the present example may divide the active portion 120 in a top view.

The current detection pad 72 is connected to a current detection unit (not shown), and detects a current flowing through the current detection unit.

FIG. 1B illustrates arrangement of the temperature sensing diode 66, the diode wiring 60, and a metal layer 80 in a top view. In FIG. 1B, the well regions are not hatched, and the temperature sensing diode 66 and the metal layer 80 are hatched.

The semiconductor substrate 10 includes the temperature sensing diode 66 provided above the upper surface of the semiconductor substrate 10. The temperature sensing diode 66 detects temperature of the semiconductor substrate 10. For example, the temperature sensing diode 66 is a PN junction diode including an anode region and a cathode region made of a semiconductor material such as polysilicon.

The semiconductor substrate 10 includes the diode wiring 60. The diode wiring 60 is provided above the upper surface of the semiconductor substrate 10, and is connected to the temperature sensing diode 66. The diode wiring 60 includes an anode wiring 60-1 and a cathode wiring 60-2. The diode wiring 60 may be made of a semiconductor material such as polysilicon, or may be made of a metal.

The anode pad 74 is connected to the anode region of the temperature sensing diode 66 via the anode wiring 60-1 of the diode wiring 60. The cathode pad 76 is connected to the cathode region of the temperature sensing diode 66 via the cathode wiring 60-2 of the diode wiring 60. For example, the temperature of the semiconductor substrate 10 is measured by measuring forward voltages of the temperature sensing diode 66 at the anode pad 74 and the cathode pad 76. The diode wiring 60, the temperature sensing diode 66, and the gate runner 48 in the present example overlap with the dividing well region 114 in a top view.

The upper surface electrode 52 and the control electrodes each contain a metal such as aluminum. An interlayer dielectric film is provided between the upper surface electrode 52 and each control electrode, and the semiconductor substrate 10. The upper surface electrode 52 and the semiconductor substrate 10 are connected to each other via a contact hole provided in the interlayer dielectric film. FIG. 1B does not show the interlayer dielectric film and the contact hole.

The upper surface electrode 52 in the present example does not overlap with the diode wiring 60 in a top view. The upper surface electrode 52 in the present example does not overlap with the temperature sensing diode 66 in a top view, either. The diode wiring 60 and the temperature sensing diode 66 in the present example are sandwiched between the first portion 52-1 and the second portion 52-2 in a top view. The diode wiring 60 and the temperature sensing diode 66 in the present example are sandwiched between the active portion 120-1 and the active portion 120-2 in a top view.

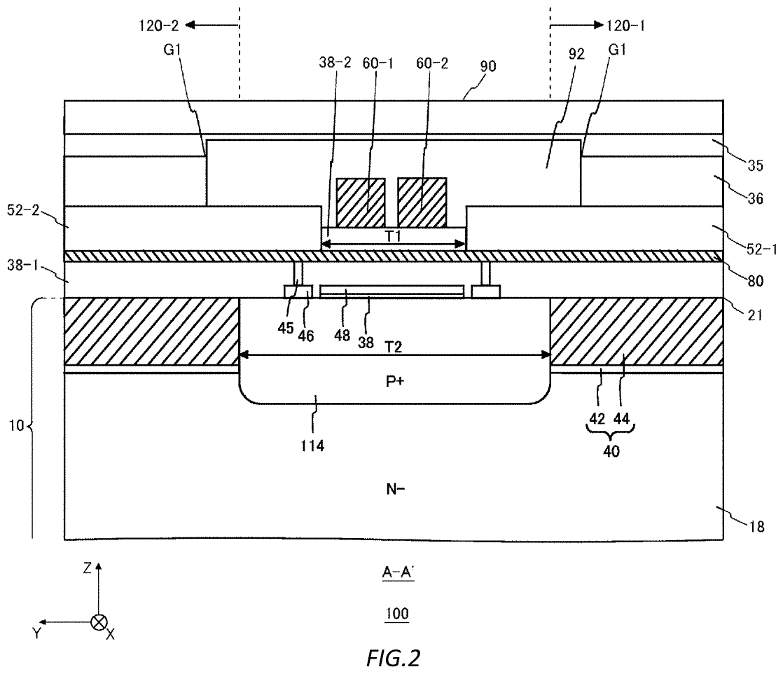

The semiconductor substrate 10 includes the metal layer 80. The metal layer 80 is provided in at least part of a region between the diode wiring 60 and the upper surface of the semiconductor substrate 10 (see FIG. 2). FIG. 1B shows only the metal layer 80 provided near the diode wiring 60. It is to be noted that the metal layer 80 may also be provided in a region other than a range overlapping with the diode wiring 60 in a top view. For example, the metal layer 80 is also provided in the active portion 120.

The semiconductor substrate 10 may include an edge termination structure portion between the peripheral well region 113 and the end side 102 of the semiconductor substrate 10. The edge termination structure portion reduces electric field strength in the semiconductor substrate 10 on a side of the upper surface thereof. The edge termination structure portion has, for example, a guard ring annularly provided enclosing the active portion 120, a field plate, a RESURF, and a structure combining them. The present specification does not illustrate the edge termination structure portion.

FIG. 2 illustrates one example of the semiconductor device 100 in a cross section A-A′ shown in FIG. 1B. The cross section A-A′ is a YZ cross section perpendicular to a direction in which the diode wiring 60 extends (the X axis direction). In the cross section, the semiconductor device 100 includes the semiconductor substrate 10, solder 35, plating 36, an interlayer dielectric film 38, the gate runner 48, the upper surface electrode 52, the diode wiring 60, the metal layer 80, a lead frame 90, and a wiring protection film 92. In the cross section, a lower surface of the semiconductor substrate 10 is not shown.

The semiconductor substrate 10 is provided with a trench portion 40. The trench portion 40 is provided extending from an upper surface 21 to an inside of the semiconductor substrate 10. The trench portion 40 may be a gate trench. The trench portion 40 includes a dielectric film 42 and a conductive portion 44 therein. The conductive portion 44 may be electrically connected to the gate pad 50 via the gate runner 48. In FIG. 2, the conductive portion 44 is hatched. The dielectric film 42 insulates the semiconductor substrate 10 and the conductive portion from each other. It is to be noted that the trench portion 40 may be a dummy trench. In that case, the conductive portion 44 may be electrically connected to the upper surface electrode 52.

In the cross section, the dividing well region 114 of a P+ type is provided within the semiconductor substrate 10. The dividing well region 114 is provided extending from the upper surface 21 of the semiconductor substrate 10 to a depth greater than that of a lower end of the trench portion 40. An end portion, in an extending direction, of the trench portion 40 (the Y axis direction in the present example) may be located within the dividing well region 114. In the cross section, a drift region 18 of an N-type is provided below the trench portion 40 and the dividing well region 114. In addition, in FIG. 2, in order to show a size of the dividing well region 114, the trench portion 40 extending into the dividing well region 114 is not shown, but the dividing well region 114 and the conductive portion 44 are electrically insulated from each other by the dielectric film 42.

The semiconductor substrate 10 includes a first interlayer dielectric film 38-1 provided on the upper surface 21. The first interlayer dielectric film 38-1 is provided between the metal layer 80 and the upper surface 21 of the semiconductor substrate 10. The first interlayer dielectric film 38-1 may be in contact with the upper surface 21. The first interlayer dielectric film 38-1 insulates the metal layer 80 and the upper surface electrode 52, and the semiconductor substrate 10 from each other. In a case of the present example, the first interlayer dielectric film 38-1 also insulates the metal layer 80 and the gate runner 48 from each other. The interlayer dielectric film 38 is provided between the gate runner 48 and the upper surface 21 of the semiconductor substrate 10. The interlayer dielectric film 38 may be a dielectric film different from the first interlayer dielectric film 38-1.

The semiconductor substrate 10 includes the metal layer 80 provided above the upper surface 21. The metal layer 80 is provided in at least part of a region between the diode wiring 60 and the upper surface 21 of the semiconductor substrate 10. The metal layer 80 may be provided over an entire horizontal direction between the diode wiring 60 and the upper surface 21 of the semiconductor substrate 10, at a position overlapping with the diode wiring 60 in the depth direction. The metal layer 80 in the present example is provided not only below the diode wiring 60 but also in the active portion 120. The metal layer 80 may also be provided below the plating 36.

The semiconductor substrate 10 includes a second interlayer dielectric film 38-2 provided above the upper surface 21. The second interlayer dielectric film 38-2 is provided between the diode wiring 60 and the metal layer 80, and insulates the diode wiring 60 and the metal layer 80 from each other. The first interlayer dielectric film 38-1 and the second interlayer dielectric film 38-2 each include at least one of a dielectric film such as a silicate glass to which an impurity such as boron or phosphorus is added, a thermal oxide film, or another dielectric film.

The diode wiring 60 is provided above the second interlayer dielectric film 38-2. As described above, the diode wiring 60 includes the anode wiring 60-1 and the cathode wiring 60-2. The diode wiring 60 in the present example is covered with the wiring protection film 92. The wiring protection film 92 is, for example, polyimide.

The upper surface electrode 52 is provided above the metal layer 80. The upper surface electrode 52 is connected to the metal layer 80. The upper surface electrode 52 and the metal layer 80 may be mutually laminated. As described above, the upper surface electrode 52 includes the first portion 52-1 and the second portion 52-2. In a top view, the first portion 52-1 and the second portion 52-2 are arranged with the diode wiring 60 therebetween.

The plating 36 is provided above the upper surface electrode 52. The upper surface electrode 52 is connected to the lead frame 90, which is a wiring member, via the plating 36. The plating 36 is, for example, Ni plating. Providing the plating 36 can improve wettability of the upper surface electrode 52 and the solder 35, which is a bonding member, and increase bondability of the lead frame 90. The plating 36 may be provided over an entirety of an upper surface of the upper surface electrode 52, or may be provided over most of the upper surface of the upper surface electrode 52 (for example, larger than or equal to half of area of the upper surface).

The solder 35 is provided above the plating 36. In the present example, the solder 35 is provided between the lead frame 90 and the plating 36. In addition, in FIG. 2, the solder 35 is also provided above the wiring protection film 92. In the present example, the solder 35 is provided between the lead frame 90 and the wiring protection film 92. It is to be noted that the solder 35 may not be provided above the wiring protection film 92.

The lead frame 90 is provided above the solder 35. The upper surface electrode 52 is connected to an external circuit via the lead frame 90.

At least part of the solder 35 may be provided at a same height as that of the wiring protection film 92. In addition, the wiring protection film 92 is provided at a position lower than the lead frame 90 in a height direction (a Z axis direction). In the present example, the wiring protection film 92 is provided below the lead frame 90.

In the present example, there is a point where the solder 35, the plating 36, and the wiring protection film 92 come into contact. The point is referred to as a triple point G1. With presence of the triple point G1, stress repeatedly applied due to heat may cause stress concentration at the triple point G1, forming a crack from the triple point toward the upper surface 21 of the semiconductor substrate 10. In a case of the present example, the metal layer 80 can suppress development of the crack.

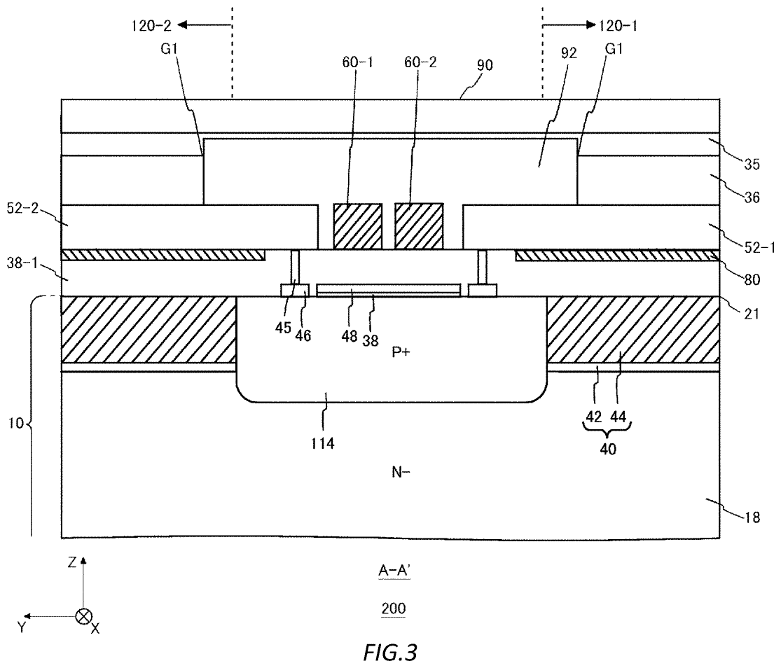

FIG. 3 illustrates a cross section A-A′ of a semiconductor device 200 according to a comparative example. In the semiconductor device 200, the metal layer 80 is not provided between the diode wiring 60 and the upper surface 21 of the semiconductor substrate 10. Accordingly, the second interlayer dielectric film 38-2 is not provided, either. Except for that, the semiconductor device 200 has a configuration similar to that of the semiconductor device 100.

In the semiconductor device 200, between the diode wiring 60 and the upper surface 21 of the semiconductor substrate 10, the metal layer 80 is not provided, and only the first interlayer dielectric film 38-1 with low strength and the gate runner 48 made of polysilicon are provided. Therefore, if the crack from the triple point G1 described above develops between the diode wiring 60 and the upper surface 21 of the semiconductor substrate 10, the development of the crack may not be suppressed. This may result in, for example, a problem such as development of the crack in the first interlayer dielectric film 38-1, causing continuity between the diode wiring 60 and the gate runner 48.

On the other hand, in the semiconductor device 100 according to an embodiment, the metal layer 80 provided between the diode wiring 60 and the upper surface 21 of the semiconductor substrate 10 can improve strength of a part below the diode wiring 60. This makes it possible to suppress the development of the crack to the part below the diode wiring 60. Further, providing the metal layer 80 between the diode wiring 60 and the upper surface 21 of the semiconductor substrate 10 can protect the diode wiring 60 from noise in the semiconductor substrate 10. In addition, the second interlayer dielectric film 38-2 can also improve the strength of the part below the diode wiring 60, and protect the diode wiring 60 from the noise.

The metal layer 80 may be composed of an electrically conductive material. This increases an effect of protection against noise. In addition, from a viewpoint of improving the strength, it is preferable that hardness of the metal layer 80 is high. For example, the metal layer 80 contains a metal harder than aluminum. The metal layer 80 and the upper surface electrode 52 may be made of different materials. The metal layer 80 may contain a harder metal than the upper surface electrode 52. The metal layer 80 may contain at least one of tungsten, titanium, or tantalum. This can further improve the strength of the part below the diode wiring 60.

In FIG. 2, side surfaces of the second interlayer dielectric film 38-2 may be in contact with the upper surface electrode 52. One of the side surfaces of the second interlayer dielectric film 38-2 in the present example is in contact with the first portion 52-1, and another is in contact with the second portion 52-2. In other words, the second interlayer dielectric film 38-2 is sandwiched between upper surface electrodes 52 in a direction (the Y axis direction) perpendicular to the direction in which the diode wiring 60 extends (the X axis direction), in a plane parallel to the upper surface 21.

The metal layer 80 in the present example is provided extending from the first portion 52-1, passing below the diode wiring 60, to the second portion 52-2. This makes it possible to cover an entire surface of the part below the diode wiring 60, so that the semiconductor device 100 more reliably achieves improvement of the strength and the effect of protection against noise.

The diode wiring 60 in the present example overlaps with the dividing well region 114 in the depth direction. The first interlayer dielectric film 38-1 in the present example is provided with a contact hole 45 which electrically connects the metal layer 80 and the dividing well region 114 to each other. The upper surface electrode 52 is electrically connected to the dividing well region 114 via the contact hole 45. This makes a potential of the dividing well region 114 equal to a potential of the upper surface electrode 52, so that the diode wiring 60 and the gate runner 48 provided above the dividing well region 114 can be protected from the noise in the semiconductor substrate 10.

A connection portion 46 may be provided below the contact hole 45. The connection portion 46 may be made of a same material as that of the gate runner 48. That is, the connection portion 46 may be a wiring made of polysilicon to which an impurity is added. Providing the connection portion 46 makes it easier to electrically connect the dividing well region 114 and the upper surface electrode 52 to each other.

The first interlayer dielectric film 38-1 in the present example is provided with two contact holes 45. The gate runner 48 in the present example is provided between the two contact holes 45 in a top view.

The dividing well region 114 in the present example is sandwiched between the active portions 120 in the Y axis direction. That is, the dividing well region 114 crosses the active portion 120. End portions of the active portions 120 in the Y axis direction shown in FIG. 2 may match end portions of the dividing well region 114.

In the cross section A-A′, a width T1 of the second interlayer dielectric film 38-2 in a horizontal direction parallel to the upper surface 21 of the semiconductor substrate 10 may be smaller than a width T2 of the dividing well region 114. In the cross section A-A′, an entirety of the second interlayer dielectric film 38-2 may overlap with the dividing well region 114.

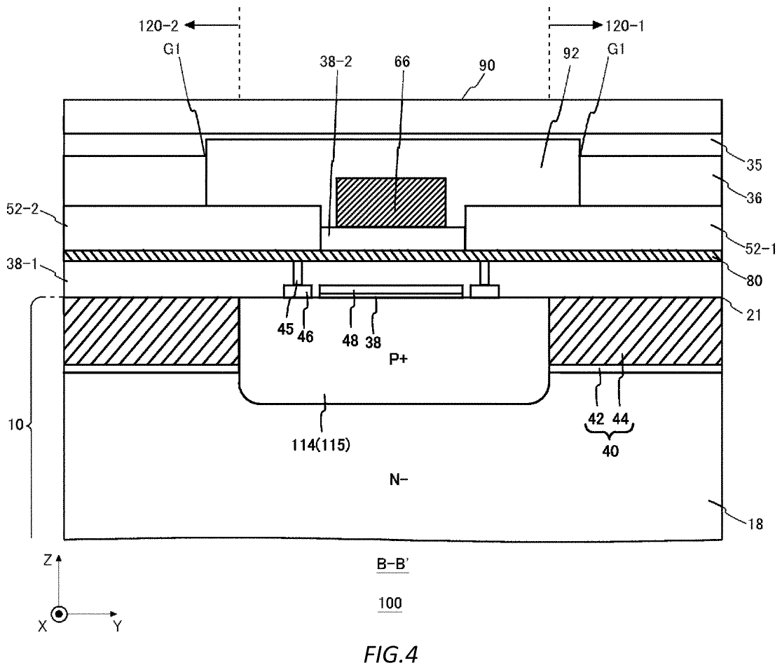

FIG. 4 illustrates one example of the semiconductor device 100 in a cross section B-B′ shown in FIG. 1B. The cross section B-B′ is a YZ cross section perpendicular to the direction in which the diode wiring 60 extends (the X axis direction). A configuration similar to that of the cross section A-A′ shown in FIG. 2 will not be described as appropriate.

The cross section is a cross section crossing the temperature sensing diode 66. The temperature sensing diode 66 is provided above the upper surface 21 of the semiconductor substrate 10. A position of the temperature sensing diode 66 in the Z axis direction may be the same as a position of the diode wiring 60. The temperature sensing diode 66 in the present example is covered with the wiring protection film 92. The temperature sensing diode 66 in the present example overlaps with the gate runner 48 in the Z axis direction.

The metal layer 80 in the present example is also provided in at least part of a region between the temperature sensing diode 66 and the upper surface 21 of the semiconductor substrate 10. Arrangement of the first interlayer dielectric film 38-1 and the second interlayer dielectric film 38-2 is similar to that in FIG. 2. The second interlayer dielectric film 38-2 in the present example insulates the metal layer 80 and the temperature sensing diode 66 from each other. This makes it possible to improve strength of a part below the temperature sensing diode 66 similarly to a case of the diode wiring 60. In addition, this makes it possible to protect the temperature sensing diode 66 from noise. The metal layer 80 may be provided over an entire horizontal direction between the temperature sensing diode 66 and the upper surface 21 of the semiconductor substrate 10, at a position overlapping with the temperature sensing diode 66 in the depth direction. The metal layer 80 provided below the temperature sensing diode 66 may also be continuous with the metal layer 80 provided in the active portion 120.

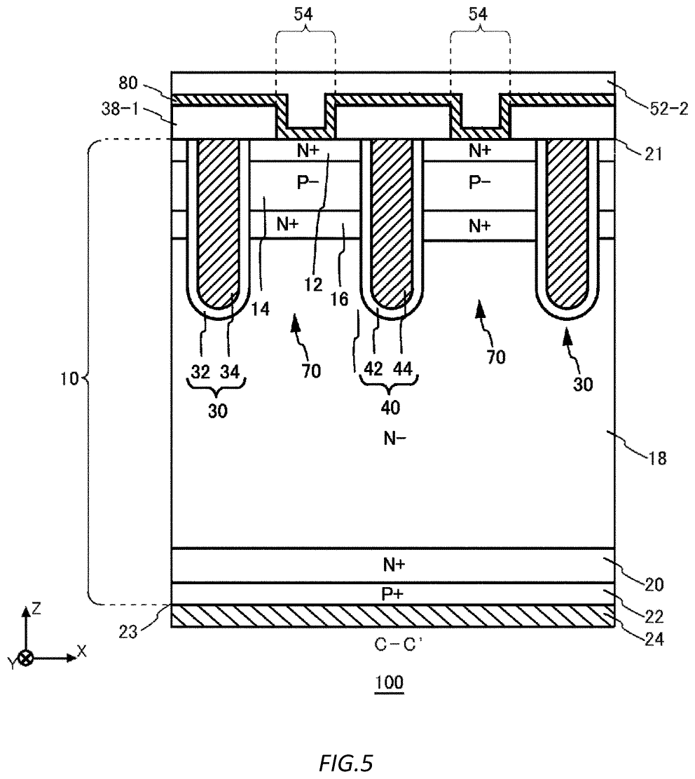

FIG. 5 illustrates one example of the semiconductor device 100 in a cross section C-C′ shown in FIG. 1B. The cross section C-C′ is an XZ cross section crossing the active portion 120. In the cross section, the semiconductor substrate 10 is provided with an IGBT. It is to be noted that the semiconductor substrate 10 may be provided with a MOSFET, or may be provided with a diode.

In the cross section C-C′, the semiconductor device 100 includes the semiconductor substrate 10, the first interlayer dielectric film 38-1, the metal layer 80, the upper surface electrode 52, and a lower surface electrode 24. The first interlayer dielectric film 38-1 is provided on the upper surface 21 of the semiconductor substrate 10. The first interlayer dielectric film 38-1 may be the same as the first interlayer dielectric film 38-1 described with reference to FIG. 2 or the like. That is, the first interlayer dielectric film 38-1 may be provided extending from below the diode wiring 60 to the active portion 120.

The upper surface electrode 52 is provided above the first interlayer dielectric film 38-1. In the cross section C-C′, the second portion 52-2 of the upper surface electrode 52 is provided. The upper surface electrode 52 is in contact with part of the upper surface 21 of the semiconductor substrate 10 through a contact hole 54 formed in the first interlayer dielectric film 38-1. The upper surface electrode 52 may also be considered to be in contact with the upper surface 21 of the semiconductor substrate 10 if it is in contact with the upper surface 21 via the metal layer 80. A tungsten plug or the like for contact may be provided between the upper surface 21 of the semiconductor substrate 10 and the upper surface electrode 52. The upper surface electrode 52 may also be considered to be in contact with the upper surface 21 of the semiconductor substrate 10 if it is in contact with the upper surface 21 via the tungsten plug.

The metal layer 80 is provided between the first interlayer dielectric film 38-1 and the upper surface electrode 52. The metal layer 80 in the present example is electrically connected to the upper surface electrode 52 in the cross section C-C′.

The metal layer 80 may be in contact with the upper surface 21 of the semiconductor substrate 10 in a region which does not overlap with the diode wiring 60 and the temperature sensing diode 66. The metal layer 80 in the present example is in contact with the upper surface 21 of the semiconductor substrate 10 via the contact hole 54 in the first interlayer dielectric film 38-1 in the cross section C-C′. The metal layer 80 may be in contact with a plurality of mesa portions 70. The metal layer 80 may be provided above a plurality of trench portions.

The metal layer 80 may function as a barrier metal in the active portion 120. Providing the metal layer 80 in the active portion 120 can prevent a resin ion from a protective film or the like provided above the upper surface electrode 52 from penetrating into the semiconductor substrate 10. The metal layer 80 may be provided extending from below the diode wiring 60 to the active portion 120. The metal layer 80 may have a same composition as that of the metal layer 80 below the diode wiring 60. This allows simplification of a manufacturing process. The metal layer 80 may have a same film thickness as that of the metal layer 80 below the diode wiring 60. This improves in-plane uniformity.

The lower surface electrode 24 is provided on the lower surface 23 of the semiconductor substrate 10. The upper surface electrode 52 and the lower surface electrode 24 are each made of a metal material such as aluminum.

The semiconductor substrate 10 includes the drift region 18 of the N-type. The drift region 18 may be a region, which is left without a dopant implanted thereinto, of the semiconductor substrate 10.

An emitter region 12 of an N+ type is provided on the upper surface 21 of the semiconductor substrate 10. The emitter region 12 in the present example is in contact with the metal layer 80 on the upper surface 21. In the depth direction, a base region 14 of a P-type is provided between the emitter region 12 and the drift region 18. An accumulation region 16 of the N+ type may be provided between the base region 14 and the drift region 18. In another cross section of the active portion 120, a contact region of the P+ type may be provided on the upper surface 21 of the semiconductor substrate 10.

One or more trench portions 40 and one or more dummy trench portions 30 are provided in the semiconductor substrate 10 on a side of the upper surface 21. The trench portion 40 may be a gate trench. Each trench portion extends from the upper surface 21 of the semiconductor substrate 10, penetrating through the base region 14, to reach the drift region 18. In a region provided with at least one of the emitter region 12, the contact region, or the accumulation region 16, each trench portion also penetrates through the doping region, to reach the drift region 18. Each trench portion penetrating through the doping region is not limited to manufacture performed by forming the doping region and then forming each trench portion. Each trench portion penetrating through the doping region also includes manufacture performed by forming each trench portion and then forming doping regions between respective trench portions. A region sandwiched between the respective trench portions within the semiconductor substrate 10 is referred to as a mesa portion 70.

The trench portion 40 includes a trench provided on the upper surface 21 of the semiconductor substrate 10, the dielectric film 42 and the conductive portion 44. The dielectric film 42 is provided covering an inner wall of the trench. The dielectric film 42 may be formed by oxidizing or nitriding a semiconductor on the inner wall of the trench. The conductive portion 44 is provided farther inward than the dielectric film 42 within the trench. That is, the dielectric film 42 insulates the conductive portion 44 and the semiconductor substrate 10 from each other. The conductive portion 44 is made of a conductive material such as polysilicon.

The conductive portion 44 may be provided to be longer than the base region 14 in the depth direction. The conductive portion 44 is electrically connected to the gate runner 48. In response to application of a predetermined gate voltage to the conductive portion 44, a channel is formed by an electron inversion layer in a surface layer, which is in contact with the trench portion 40 and is a boundary surface between the base region 14 and the trench portion 40, of the base region 14.

The dummy trench portion 30 may have a same structure as that of the trench portion 40 in the cross section. The dummy trench portion 30 includes a dummy trench provided on the upper surface 21 of the semiconductor substrate 10, a dummy dielectric film 32, and a dummy conductive portion 34. The dummy conductive portion 34 is electrically connected to the upper surface electrode 52 in another cross section. The dummy dielectric film 32 is provided covering an inner wall of the dummy trench. The dummy conductive portion 34 is provided within the dummy trench, and is provided farther inward than the dummy dielectric film 32. The dummy dielectric film 32 insulates the dummy conductive portion 34 and the semiconductor substrate 10 from each other. The dummy conductive portion 34 may be made of a same material as that of the conductive portion 44. For example, the dummy conductive portion 34 is made of a conductive material such as polysilicon. The dummy conductive portion 34 may have a same length as that of the conductive portion 44 in the depth direction.

The trench portion 40 and the dummy trench portion 30 in the present example are each covered with the first interlayer dielectric film 38-1 on the upper surface 21 of the semiconductor substrate 10. It should be noted that bottom portions of the dummy trench portion 30 and the trench portion 40 may each have a curved surface (be curved in the cross section) protruding downward. End portions, in the Y axis direction, of the trench portion 40 and the dummy trench portion 30 may be covered with the dividing well region 114 (see FIG. 2 and FIG. 4). It is to be noted that a gate provided in the semiconductor substrate 10 is not limited to a trench type. The semiconductor substrate 10 may be provided with a planar gate.

A buffer region 20 of the N+ type may be provided below the drift region 18. A doping concentration in the buffer region 20 is higher than a doping concentration in the drift region 18. The buffer region 20 may function as a field stopper layer which prevents a depletion layer expanding from a lower end of the base region 14 from reaching a collector region 22 of the P+ type.

The collector region 22 of the P+ type is provided below the buffer region 20. An acceptor concentration in the collector region 22 is higher than an acceptor concentration in the base region 14. The collector region 22 may include an acceptor which is the same as or different from an acceptor in the base region 14. The acceptor in the collector region 22 is, for example, boron.

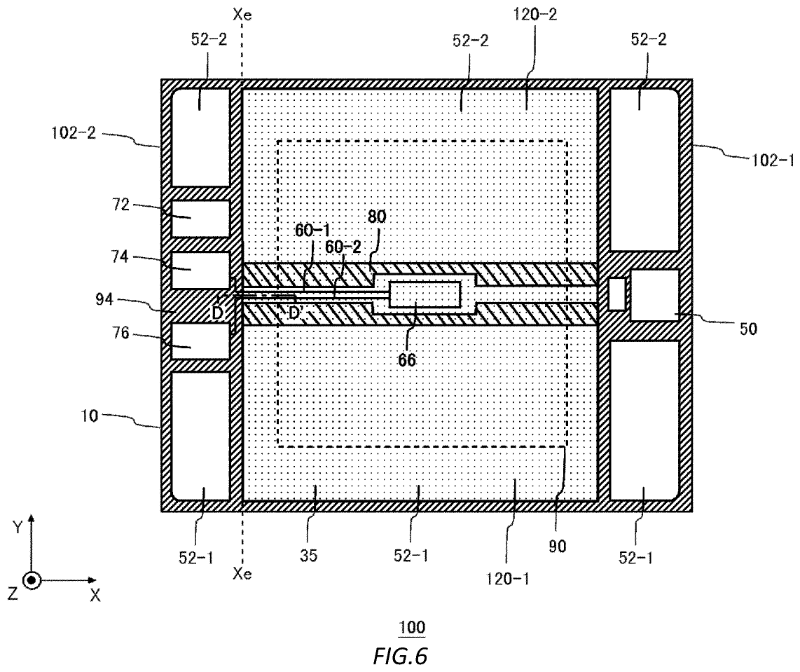

FIG. 6 illustrates one example of a top view of the semiconductor device 100. FIG. 6 shows positions of the solder 35, the lead frame 90, and a protective film 94.

The protective film 94 is provided above the upper surface 21 of the semiconductor substrate 10. Protective films 94 are arranged so as to sandwich the active portion 120 of the semiconductor substrate 10 in a top view. The protective film 94 may enclose the active portion 120 in a top view. Dark hatching in FIG. 6 represents the protective film 94. The protective film 94 separates the gate pad 50, the current detection pad 72, the anode pad 74, and the cathode pad 76 from the active portion 120 in a top view. The protective film 94 may also separate portions of the upper surface electrode 52 which face respective control electrodes in the Y axis direction from portions thereof which do not face the respective control electrodes in the Y axis direction. The protective film 94 is, for example, polyimide.

In the active portion 120, the solder 35 is provided above the upper surface electrode 52. In a top view, a range provided with the solder 35 is defined by the protective film 94. The solder 35 in the present example is formed over an entire area of the active portion 120 enclosed by the protective film 94. In FIG. 6, a range where the solder 35 is formed is indicated by light hatching.

An end portion of the solder 35 in the direction in which the diode wiring 60 extends (the X axis direction) is referred to as an end portion position Xe. In other words, the solder 35 is provided extending to the end portion position Xe in the direction in which the diode wiring 60 extends. End portion positions Xe in the present example match end portions of the protective films 94 sandwiching the active portion 120. It is to be noted that the end portion position Xe may not match an end portion of the protective film 94 enclosing the active portion 120. The end portion position Xe may be located farther inward, at the semiconductor substrate 10, than the end portion of the protective film 94 in a top view. In addition, if the end portion positions Xe differ from one position to another in a direction (the Y axis direction) perpendicular to the direction in which the diode wiring 60 extends, an end portion of the solder 35 at a position where the triple point G1 (see FIG. 2) is formed may be referred to as the end portion position Xe. That is, the triple point G1 is formed from a side of the temperature sensing diode 66 of the diode wiring 60 to the end portion position Xe. The lead frame 90 is provided above the solder 35.

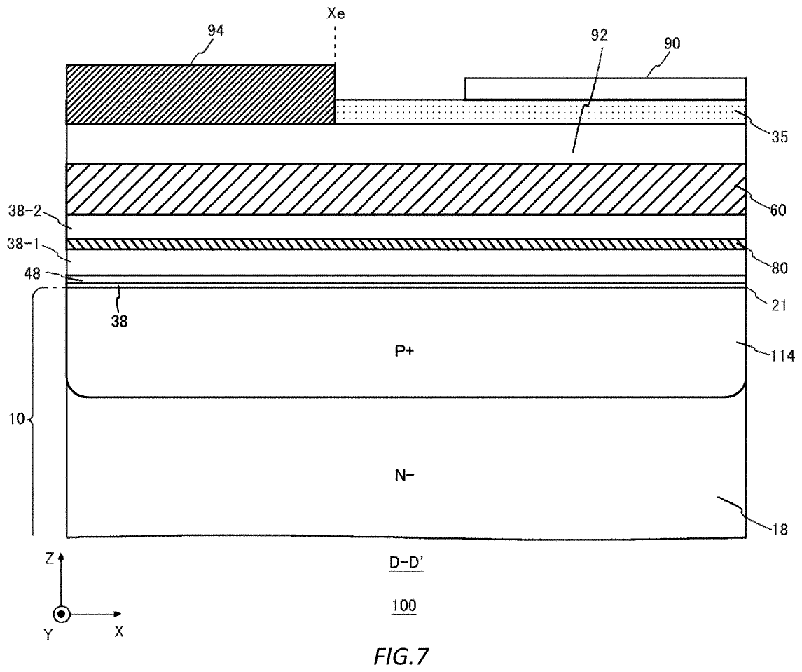

FIG. 7 illustrates one example of the semiconductor device 100 in a cross section D-D′ shown in FIG. 6. The cross section D-D′ is an XZ cross section crossing the protective film 94 from the diode wiring 60. The solder 35 in the present example is also provided above the wiring protection film 92. It is to be noted that the solder 35 may not be provided above the wiring protection film 92.

The metal layer 80 is provided below the diode wiring 60 at the end portion position Xe in an extending direction in the present example (the X axis direction). Among the triple points described above, stress is particularly easily generated in a boundary portion where the solder 35 is no longer formed. Therefore, a crack is easily formed starting from the triple point at the end portion position Xe. Providing the metal layer 80 below the end portion position Xe can increase strength of a part below the diode wiring 60 near a position where the crack is easily formed. If the diode wiring 60 and the end portion position Xe do not overlap with each other in the depth direction, the metal layer 80 may be provided below the diode wiring 60 at a position obtained by extending the end portion position Xe to a position where it overlaps with the diode wiring 60 in the Y axis direction.

The metal layer 80 may be provided extending to a position farther outward than the end portion position Xe of the solder 35 (a position on a negative side of an X axis). The metal layer 80 may be formed over a distance of at least 10 μm in the direction in which the diode wiring 60 extends, with the end portion position Xe as a center. The distance may be 20 μm, or may be 100 μm. The metal layer 80 may be provided continuously extending from the side of the temperature sensing diode 66 of the diode wiring 60 to the end portion position Xe.

In a top view, the metal layer 80 may be provided below an end portion of the protective film 94 overlapping with the diode wiring 60. The end portion of the protective film 94 in the present example matches the end portion position Xe of the solder 35. The end portion position Xe of the solder 35 is often defined by the end portion of the protective film 94, so that providing the metal layer 80 below the end portion of the protective film 94 can increase the strength of the part below the diode wiring 60 near the position where the crack is easily formed.

The metal layer 80 may be provided extending to a position farther outward than the end portion of the protective film 94 (a position on the negative side of the X axis). The metal layer 80 may be formed over a distance of at least 10 μm in the direction in which the diode wiring 60 extends, with the end portion of the protective film 94 as a center. The distance may be 20 μm, or may be 100 μm. The metal layer 80 may be provided continuously extending from the side of the temperature sensing diode 66 of the diode wiring 60 to the end portion of the protective film 94. The metal layer 80 may be provided below end portions of all the protective films 94 sandwiching the active portion 120.

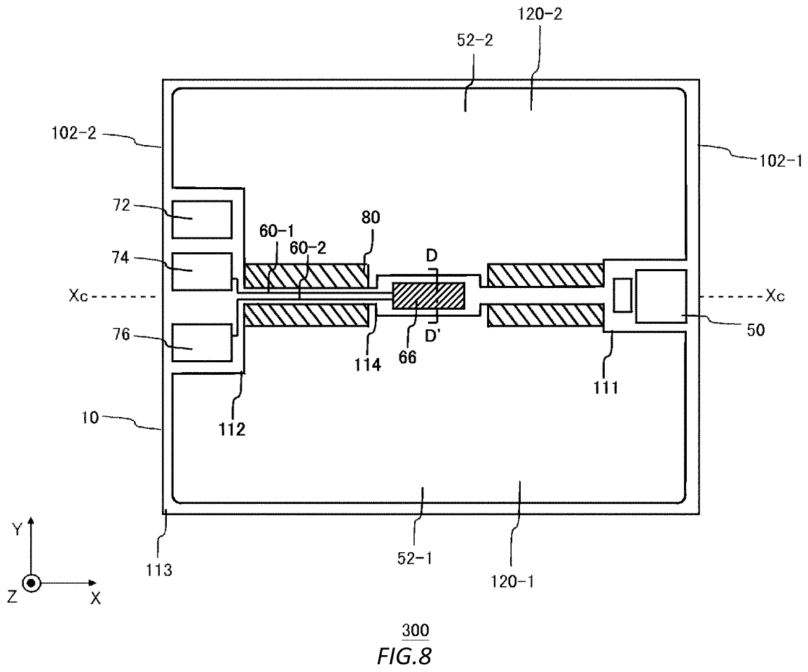

FIG. 8 illustrates a top view of one example of a semiconductor device 300 according to another embodiment of the present invention. The semiconductor device 300 in the present example is different from the semiconductor device 100 shown in FIG. 1B in that the metal layer 80 is not formed below the temperature sensing diode 66. Except for that, it is similar to the semiconductor device 100. The metal layer 80 in the present example may also be provided extending to the active portion 120.

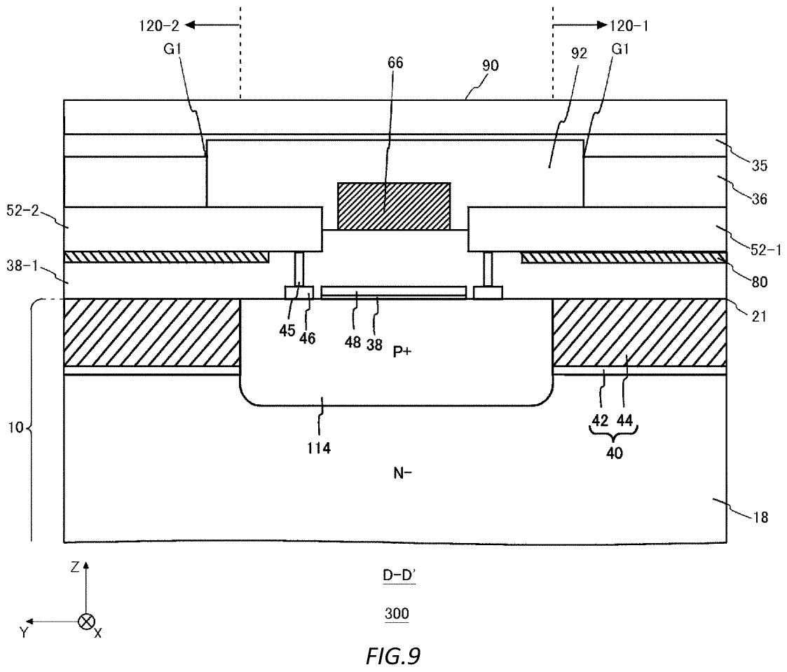

FIG. 9 illustrates one example of the semiconductor device 300 in a cross section D-D′ shown in FIG. 8. The cross section D-D′ is a YZ cross section perpendicular to the direction in which the diode wiring 60 extends (the X axis direction). The cross section D-D′ is a cross section crossing the temperature sensing diode 66.

As described above, in the semiconductor device 300, the metal layer 80 is not formed below the temperature sensing diode 66. The first interlayer dielectric film 38-1 and the gate runner 48 are formed below the temperature sensing diode 66 in the present example. Except for that, the semiconductor device 300 has a structure similar to that of the semiconductor device 100 shown in FIG. 4. As described above, a crack is easily formed starting from the triple point at the end portion position Xe. The end portion position Xe of the solder 35 in the direction in which the diode wiring 60 extends (the X axis direction) in the present example does not overlap with the temperature sensing diode 66. Therefore, there is relatively low possibility that the crack develops to below the temperature sensing diode 66. Consequently, the metal layer 80 may not be provided below the temperature sensing diode 66.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that embodiments added with such alterations or improvements can be included in the technical scope of the present invention.

What is claimed is:

1. A semiconductor device comprising a semiconductor substrate, wherein
the semiconductor substrate has:
a temperature sensing diode provided above an upper surface of the semiconductor substrate;
a diode wiring provided above the upper surface of the semiconductor substrate and connected to the temperature sensing diode;
a metal layer provided in at least part of a region between the diode wiring and the upper surface of the semiconductor substrate;
a first interlayer dielectric film provided between the metal layer and the upper surface of the semiconductor substrate; and
a second interlayer dielectric film provided between the diode wiring and the metal layer.

2. The semiconductor device according to claim 1, wherein
the metal layer is also provided in at least part of a region between the temperature sensing diode and the upper surface of the semiconductor substrate.

3. The semiconductor device according to claim 1, wherein
the metal layer contains a metal harder than aluminum.

4. The semiconductor device according to claim 3, wherein
the metal layer contains at least one of tungsten, titanium, or tantalum.

5. The semiconductor device according to claim 1, further comprising an upper surface electrode provided above the upper surface of the semiconductor substrate and in contact with part of the upper surface of the semiconductor substrate, wherein
the upper surface electrode is connected to the metal layer.

6. The semiconductor device according to claim 5, wherein
the upper surface electrode does not overlap with the diode wiring in a top view.

7. The semiconductor device according to claim 6, wherein
the metal layer contains a harder metal than the upper surface electrode.

8. The semiconductor device according to claim 6, wherein
the metal layer is in contact with the upper surface of the semiconductor substrate in a region which does not overlap with the diode wiring and the temperature sensing diode.

9. The semiconductor device according to claim 6, wherein
a side surface of the second interlayer dielectric film is in contact with the upper surface electrode.

10. The semiconductor device according to claim 6, wherein
the upper surface electrode includes a first portion and a second portion sandwiching the diode wiring in a top view, and
the metal layer is provided extending from the first portion, passing below the diode wiring, to the second portion.

11. The semiconductor device according to claim 6, wherein
the semiconductor substrate further has:
a trench portion provided extending from the upper surface to an inside of the semiconductor substrate and having a conductive portion provided therein; and
a well region provided extending from the upper surface of the semiconductor substrate to a depth greater than that of a lower end of the trench portion,
the diode wiring overlaps with the well region in a top view, and
the first interlayer dielectric film is provided with a contact hole which electrically connects the metal layer and the well region to each other.

12. The semiconductor device according to claim 11, wherein
the semiconductor substrate further has active portions each provided with a semiconductor element, and
the well region is sandwiched between the active portions in a top view.

13. The semiconductor device according to claim 11, wherein
in a cross section perpendicular to a direction in which the diode wiring extends, a width of the second interlayer dielectric film in a horizontal direction parallel to the upper surface of the semiconductor substrate is smaller than a width of the well region.

14. The semiconductor device according to claim 11, wherein
the first interlayer dielectric film is provided with two contact holes including the contact hole,
the semiconductor substrate further has a gate runner provided above the upper surface of the semiconductor substrate, and
the gate runner is provided between the two contact holes in a top view.

15. The semiconductor device according to claim 1, further comprising:
an upper surface electrode provided above the upper surface of the semiconductor substrate and in contact with part of the upper surface of the semiconductor substrate; and
solder at least part of which is provided above the upper surface electrode, wherein
in a direction in which the diode wiring extends, the solder is provided extending to an end portion position, and
the metal layer is provided below the diode wiring at the end portion position in the direction in which the diode wiring extends.

16. The semiconductor device according to claim 1, further comprising protective films provided above the semiconductor substrate and arranged so as to sandwich an active portion of the semiconductor substrate in a top view, wherein
in a top view, the metal layer is provided below end portions of the protective films overlapping with the diode wiring.

17. The semiconductor device according to claim 2, further comprising an upper surface electrode provided above the upper surface of the semiconductor substrate and in contact with part of the upper surface of the semiconductor substrate, wherein
the upper surface electrode is connected to the metal layer.

18. The semiconductor device according to claim 3, further comprising an upper surface electrode provided above the upper surface of the semiconductor substrate and in contact with part of the upper surface of the semiconductor substrate, wherein
the upper surface electrode is connected to the metal layer.

19. The semiconductor device according to claim 4, further comprising an upper surface electrode provided above the upper surface of the semiconductor substrate and in contact with part of the upper surface of the semiconductor substrate, wherein
the upper surface electrode is connected to the metal layer.

20. The semiconductor device according to claim 2, further comprising:
an upper surface electrode provided above the upper surface of the semiconductor substrate and in contact with part of the upper surface of the semiconductor substrate; and
solder at least part of which is provided above the upper surface electrode, wherein
in a direction in which the diode wiring extends, the solder is provided extending to an end portion position, and
the metal layer is provided below the diode wiring at the end portion position in the direction in which the diode wiring extends.
